(19) United States
(12) Patent Application Publication
(10) Pub. No.: US 2021/0301402 A1
(43) Pub. Date: Sep. 30, 2021

(54) FILM FORMING APPARATUS AND FILM FORMING METHOD

(71) Applicant: Tokyo Electron Limited, Tokyo (JP)

(72) Inventors: Yusuke SUZUKI, Nirasaki-shi, Yamanashi (JP); Tsuyoshi MORIYA, Nirasaki-shi, Yamanashi (JP); Tadashi MITSUNARI, Nirasaki-shi, Yamanashi (JP); Shinya IWASHITA, Nirasaki-shi, Yamanashi (JP); Yoshinori MORISADA, Nirasaki-shi, Yamanashi (JP); Naotaka NORO, Boise, ID (US); Munehito KAGAYA, Nirasaki-shi, Yamanashi (JP); Satoshi TANAKA, Nirasaki-shi, Yamanashi (JP)

(21) Appl. No.: 17/265,288

(22) PCT Filed: Jul. 29, 2019
(86) PCT No.: PCT/JP2019/029697

§ 371 Date: Feb. 2, 2021

(30) Foreign Application Priority Data
Aug. 9, 2018 (JP) 2018-150525

(51) Int. Cl. C23C 16/52; C23C 16/50; C23C 16/455

(52) U.S. Cl. CPC C23C 16/52; C23C 16/45544; C23C 16/45536; C23C 16/50

(57) ABSTRACT

A film forming apparatus includes: a processing container; a support mechanism configured to support a substrate to be capable of being raised and lowered; a first gas supplier configured to supply a first gas to a front surface of the substrate supported on the support mechanism; a second gas supplier configured to supply a second gas to a rear surface of the substrate supported on the support mechanism; and a third gas supplier configured to supply a third gas to at least one of the front surface and the rear surface of the substrate supported on the support mechanism.

### CROSS-REFERENCE OF THE APPLICATION

This is a National Phase Application filed under 35 U.S.C. 371 as a national stage of PCT/JP2019/029697, filed Jul. 29, 2019, an application claiming the benefit of Japanese Application No. 2018-150525, filed Aug. 9, 2018, the content of each of which is hereby incorporated by reference in its entirety.

### TECHNICAL FIELD

The present disclosure relates to a film forming apparatus and a film forming method.

### BACKGROUND

When a film is formed on a substrate, the substrate may warp due to the stress of the film. Therefore, for example, in Patent Document 1, provided is a plasma CVD apparatus, in which a reaction chamber on the front surface side and a reaction chamber on the rear surface side of a sample are formed, and homogeneous films are formed on both the front and rear surfaces of the sample, whereby it is possible to prevent warpage and cracking of the sample after the film formation.

### PRIOR ART DOCUMENTS

### Patent Documents

Patent Document 1: Japanese Laid-Open Patent Publication No. 2003-27242

The present disclosure provides a technique capable of compensating for warpage of a substrate.

### SUMMARY

According to one embodiment of the present disclosure, there is provided a film forming apparatus including: a processing container; a support mechanism configured to support a substrate to be capable of being raised and lowered; a first gas supplier configured to supply a first gas to a front surface of the substrate supported on the support mechanism; a second gas supplier configured to supply a second gas to a rear surface of the substrate supported on the support mechanism; and a third gas supplier configured to supply a third gas to at least one of the front surface and the rear surface of the substrate supported on the support mechanism.

According to an embodiment of the present disclosure, it is possible to compensate for warpage of a substrate.

### BRIEF DESCRIPTION OF DRAWINGS

FIG. 1 is a schematic view illustrating an exemplary film forming apparatus according to an embodiment.

FIGS. 2A and 2B are views illustrating an exemplary substrate support mechanism according to an embodiment.

FIGS. 3A to 3C are views illustrating exemplary operation of lifter pins according to an embodiment.

FIG. 4 is a schematic view illustrating a planar density distribution of film formation according to an embodiment.

FIGS. 5A and 5B are schematic views illustrating exemplary film formation on front and rear surfaces of a substrate according to an embodiment.

FIG. 6 is a view illustrating gas supply during film formation on a rear surface according to an embodiment.

### DETAILED DESCRIPTION

Hereinafter, exemplary embodiments for executing the present disclosure will be described with reference to drawings. In the specification and drawings, constituent elements that are substantially the same will be denoted by the same reference numerals, and redundant descriptions will be omitted.

### INTRODUCTION

In, for example, a process of forming multiple layers of films on a wafer in multiple layers, when the films are formed on the front surface of the wafer, the wafer may warp due to the stress of the films. As an example, when a wafer is placed on a stage that has become hot in a step after formation of an SiO₂ film and an SiN film in a 3D NAND process, a Si substrate on the rear surface of the wafer may expand due to heat, and the front surface of the wafer may warp in a concave shape. The warpage of the wafer may have an effect that makes a process difficult in a step subsequent to the film formation.

Conventionally, there is a method of forming a film on the rear surface of a wafer as a method of suppressing the warpage of a wafer. However, when forming a film on the rear surface of the wafer, the gas may wrap around to the front surface and a film may be formed on the front surface of the wafer. In addition, when the wafer is heated by the radiation of a heater, the heating rate of the wafer may be slowed down. In particular, when a film is formed on the rear surface of a wafer, a device structure is formed on the front surface. Thus, since the front surface side of the wafer cannot be placed on the stage, it takes time to raise the temperature of the wafer.

Therefore, the film forming apparatus and the film forming method according to an embodiment described below compensate for the warpage of a wafer by forming a stress-adjusted film on the rear surface of the wafer. The problem in which when a film is formed on the rear surface of a wafer, a film is formed on the front surface of the wafer due to the gas wrapping around the front surface of the wafer, and the problem in which the temperature rise rate of the wafer is low are solved by supplying heated He purge gas to the surface on the side on which no film is formed. In addition, a mechanism for forming a film while switching between the front surface and the rear surface of the wafer is provided in a single processing container. As a result, in the film forming apparatus according to an embodiment, a composite process in which different types of films are alternately formed can be executed. For example, in a process of forming a film A and a film B, if the stress of the film A is too high, there is a risk that the warpage of the wafer adversely affects the result of the process when the film B is formed. At this time, if a film that compensates for stress can be formed on the rear surface immediately after the film A is formed, the film B can be stably formed.

[Configuration of Film Forming Apparatus]

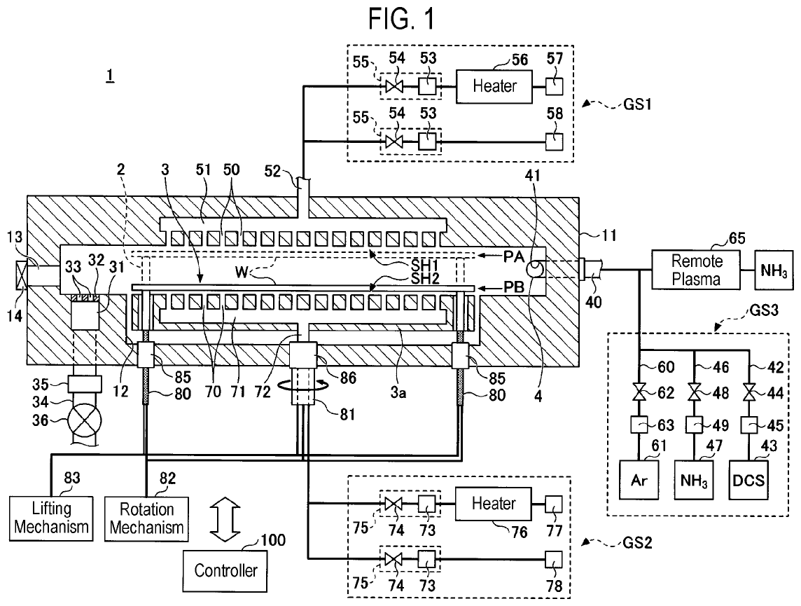

First, the configuration of a film forming apparatus 1 according to an embodiment of the present disclosure will be described with reference to FIG. 1. FIG. 1 is a vertical cross-sectional view illustrating an exemplary configuration of the film forming apparatus 1 according to an embodiment. In an embodiment, the film forming apparatus 1 implements a so-called atomic layer deposition (ALD) method in which film formation is performed by alternately supplying a raw material gas and a reaction gas to a substrate so as to laminate atomic layers or molecular layers.

The film forming apparatus 1 has a processing container 11, which is a vacuum container in which a film forming process is performed on a wafer W. On the side wall surface of the processing container 11, a carry-in/out port 13 for carrying in and out a wafer W therethrough and a gate valve 14 configured to open/close the carry-in/out port 13 are installed.

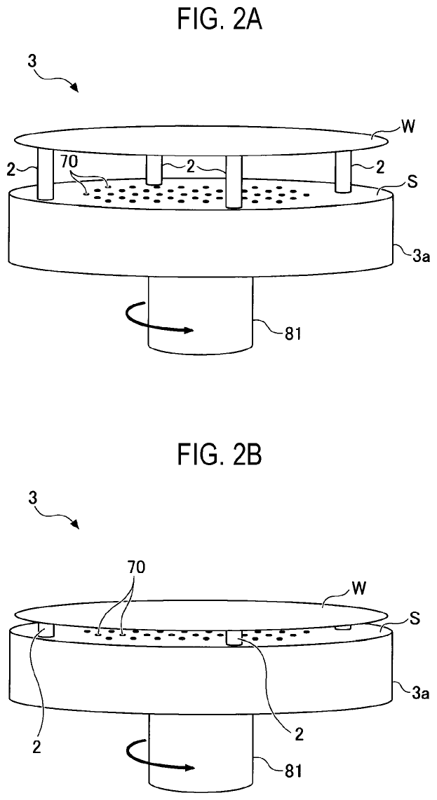

A gas shower head SH1 is formed on the ceiling of the processing container 11. In a recess 12 formed in the bottom portion of the processing container 11, a stage 3a in which a gas shower head SH2 is formed is accommodated to face the gas shower head SH1. A support mechanism 3 has a plurality of lifter pins 2 that penetrate the stage 3a and support a wafer W to be capable of being raised and lowered. In the present embodiment, as illustrated in FIGS. 2A and 2B, a wafer W is supported by four lifter pins 2 to be capable being raised and lowered, but the number of the lifter pins 2 is not limited thereto, and may be three or five or more.

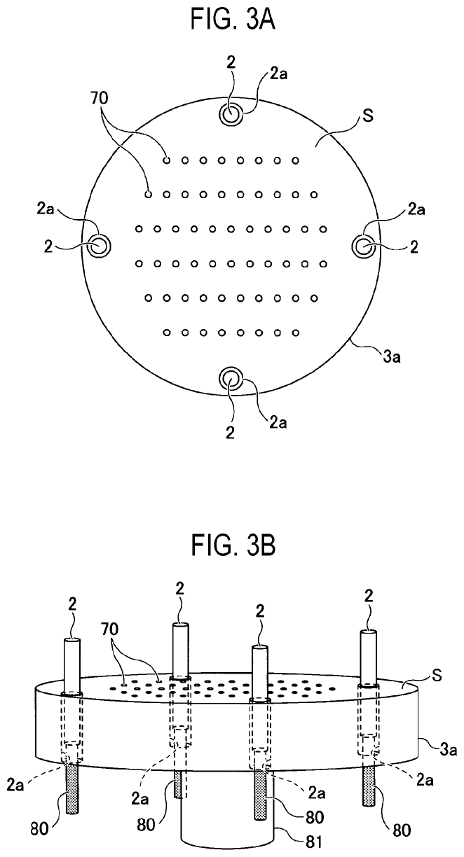

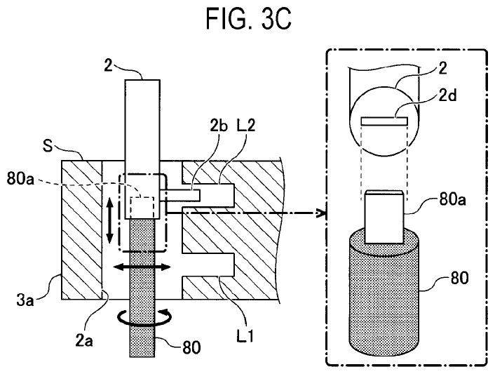

FIG. 3A illustrates a top surface S (front surface) view of the stage 3a, and FIG. 3B illustrates a perspective view of the stage 3a. Four pin holes 2a are formed on the outer peripheral side of the stage 3a, and the lifter pins 2 penetrates pin holes 2a. When a wafer W is held and supported at the upper ends of the lifter pins 2 (see FIGS. 2A and 2B) and the stage 3a reaches the initial position, the lifter pins 2 are pushed up from below by pin-up jigs 80. As illustrated in FIG. 1, the portions where the jigs 80 penetrate the bottom portion of the processing container 11 are sealed with magnetic seals 85, and the jigs 80 are fixed to the bottom portion of the processing container 11.

After the lifter pins 2 are lifted up at the initial position illustrated in FIG. 3B, as illustrated in FIG. 3C, the lifter pins 2 cause lock portions 2b, which protrude horizontally from the lifter pins 2, respectively, to be inserted into respective recessed portions L2 formed horizontally from the pin holes 2a in the stage 3a. As a result, the lock portions 2b are locked and the wafer W is fixed at the lift-up position.

A screw hole 2d is formed below each lifter pin 2, and a protrusion 80a at the tip of each jig 80 is inserted into the screw hole 2d. A rotation mechanism 82 and a lifting mechanism 83 illustrated in FIG. 1 are connected to the lifter pins 2 via the jigs 80. By rotating the jigs 80 by the rotation mechanism 82, the lifter pins 2 are rotated, whereby the lock portions 2b can be inserted into the recessed portions L2 and locked. The lifter pins 2 are lowered by the lifting mechanism 83, and the lock portions 2b are inserted into respective recessed portions L1 at the initial position and unlocked. When raising and lowering the lifter pins, the jigs 80 are moved laterally to the side opposite to the recessed portions L2 so that the lock portions 2b do not interfere with the side walls of the pin holes 2a.

The rotation mechanism 82 and the lifting mechanism 83 illustrated in FIG. 1 are connected to a support 81 that supports the stage 3a. The rotation mechanism 82 rotates the stage 3a by the power of a motor. As a result, the wafer W supported by the support mechanism 3 rotates. In addition, the lifting mechanism 83 is capable of raising and lowering the stage 3a by the power of the motor.

The portion where the support 81 penetrates the bottom portion of the processing container 11 is sealed with a magnetic seal 86. The magnetic seals 85 and 86 shield the inside of the processing container 11 from the outside of the processing container 11 so as to maintain the vacuum state inside the processing container 11.

Inside the processing container 11, an exhaust groove 31 having a rectangular cross section is formed at one end side in the lengthwise direction (the left-right direction of the paper surface). In the lengthwise direction of the processing container 11, one end side at which the exhaust groove 31 is arranged is also referred to as a “downstream side”, and the side opposite the side at which the exhaust groove 31 is arranged is also referred to as an “upstream side”.

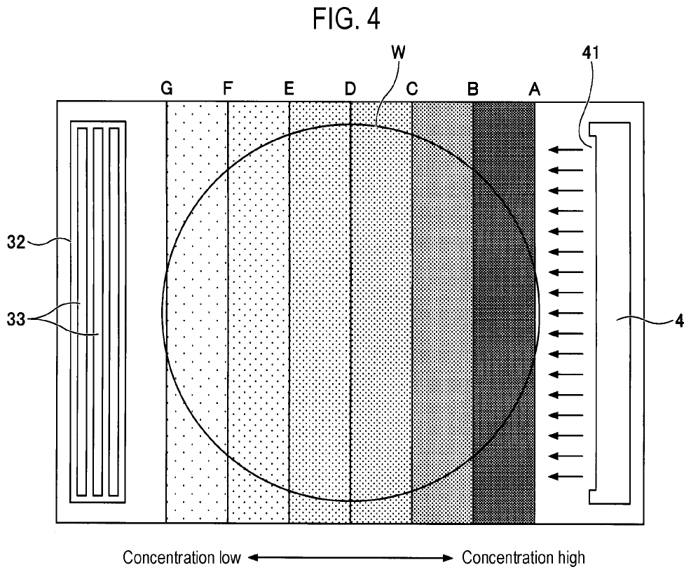

The exhaust groove 31 is open to the bottom surface of the processing container 11. A lid 32 is installed at the opening of the exhaust groove 31. As illustrated in FIG. 4, the lid 32 extends in the widthwise direction of the processing container 11, and a plurality of slits 33 arranged in the lengthwise direction of the processing container 11 are formed in the lid 32. Returning back to FIG. 1, an exhaust pipe 34 is connected to the bottom portion of the exhaust groove 31, a pressure adjustment part 35 and an exhaust valve 36 are installed in the exhaust pipe 34 from the exhaust groove 31 side and are connected to a vacuum pump (not illustrated).

A film formation gas ejection part 4 is installed at the upstream side in the processing container 11. As illustrated in FIG. 4, the film formation gas ejection part 4 is provided with a slit 41 extending in the lengthwise direction of the film formation gas ejection part 4 so as to open towards the front side (downstream side). The slit 41 is longer than the width dimension of the wafer W when viewed in a plane, and is formed such that the film formation gas ejected from the film formation gas ejection part 4 passes through the entire surface of the wafer W.

Returning back to FIG. 1, a gas supply pipe 40 is connected to the film formation gas ejection part 4. A third gas supply source GS3 (third gas supplier) configured to supply a third gas from the side wall of the processing container 11 is connected to the gas supply pipe 40. A raw material gas supply pipe 42 configured to supplying a raw material gas, a reaction gas supply pipe 46 configured to supply a reaction gas that reacts with the raw material gas, and a replacement gas supply pipe 60 configured to supply a replacement gas are joined in the third gas supply source GS3.

A DCS supply source 43 configured to supply DCS (dichlorosilane) (hereinafter, referred to as “DCS”), which is an example of raw material gas, is connected to the raw material gas supply pipe 42, and the raw material gas supply pipe 42 is provided with a flow rate adjustment part 45 configured to adjust the flow rate of the DCS gas and a valve 44 configured to turn on/off the supply of DCS gas.

An NH₃ supply source 47 configured to supply NH₃, which is an example of the reaction gas, is connected to the reaction gas supply pipe 46, and the reaction gas supply pipe 46 is provided with a flow rate adjustment part 49 configured to adjust the flow rate of the NH₃ gas and a valve 48 configured to turn on/off the supply of the NH₃ gas. In this example, the raw material gas and the reaction gas are also referred to as “film formation gases”. DCS and NH₃ are examples of the third gas.

An Ar gas supply source 61 configured to supply Ar gas, which is an example of replacement gas (purge gas), is connected to the replacement gas supply pipe 60, and the replacement gas supply pipe 60 is provided with a flow rate adjustment part 63 configured to adjust the flow rate of Ar gas and a valve 62 configured to turn on/off the supply of Ar gas.

The third gas supply source GS3, the film formation gas ejection part 4, and the gas supply pipe 40 are an example of the third gas supplier, which supplies the third gas to at least one of the front surface or the rear surface of the wafer W supported by the support mechanism 3. Here, the third gas supplier supplies the third gas in the radial direction of the wafer W supported by the support mechanism 3.

A remote plasma generator 65 is connected to the gas supply pipe 40. The remote plasma generator 65 supplies plasma from the side wall of the processing container 11. Switching between the supply of the third gas from the third gas supply source GS3 and the supply of plasma from the remote plasma generator 65 is performed by controlling the valves 44 and 48 in the third gas supply source GS3 and the remote plasma generator 65 in the third gas supply source GS3.

A gas shower head SH1 is installed on the ceiling of the processing container 11, and a first gas supply source GS1 configured to supply a concentration adjustment gas for adjusting the concentration of the film formation gas, for example, Ar gas, which is a dilution gas, or heated He gas is connected to the gas shower head SH1 through a gas supply pipe 52.

The first gas supply source GS1 (first gas supplier) is divided into two systems, each of which is provided with a flow rate adjustment part 53 and a valve 54. The flow rate adjustment part 53 and the valve 54 are also referred to as a “gas adjustment part” 55. A He gas supply source 57 is connected to one gas adjustment part 55, and an Ar gas supply source 58 is connected to the other gas adjustment part 55. A heater 56 heats the He gas supplied from the He gas supply source 57. The heated He gas and the Ar gas supplied from the Ar gas supply source 58 are switched by the control of the valve 54, are supplied to the gas shower head SH1, and are introduced into the processing container 11 from a plurality of gas holes 50 via a buffer chamber 51. The He gas functions as a purge gas that prevents the film formation gas introducing into the front surface of the wafer W. In addition, the Ar gas functions as a dilution gas for the film formation gas.

The plurality of gas holes 50 is formed in the lengthwise direction from the upstream side to the downstream side of the gas flow of the film formation gas such as DCS supplied from the side wall of the processing container 11, and are formed in a slit shape or a hole shape extending in the widthwise direction so as to cover the entire surface of the wafer W when viewed in a plane. As a result, Ar gas, which is a diluting gas, or heated He gas is supplied from each gas hole 50 towards the front surface of the wafer W supported by the support mechanism 3 in the state in which the flow rate is uniform in the widthwise direction.

He gas is an example of the first gas. The first gas supply source GS1 and the gas shower head SH1 are an example of the first gas supplier configured to supply the first gas to the front surface of the wafer W supported on the support mechanism 3. The first gas is not limited to He gas, and an inert gas may be heated and supplied as the first gas. Further, the dilution gas supplied from the gas shower head SH1 is not limited to Ar gas, and may be an inert gas such as N₂ gas.

When a film is formed the rear surface of the wafer W, the support mechanism 3 brings the wafer W close to the first gas supplier (e.g., the position PA in FIG. 1) so as to supply the first gas and the third gas. When a film is formed on the rear surface of the wafer W, the first gas supplier supplies an inert gas such as heated He gas as the first gas so as to prevent the film from being formed on the front surface of the wafer W.

The gas shower head SH2 supplies a concentration adjustment gas for adjusting the concentration of the film formation gas, for example, Ar gas, which is a dilution gas, or heated He gas. A gas supply pipe 72 is connected to the gas shower head SH2, and a second gas supply source GS2 configured to supply a second gas is connected to the gas supply pipe 72.

The second gas supply source GS2 (second gas supplier) is divided into two systems, each of which is provided with a flow rate adjustment part 73 and a valve 74. The flow rate adjustment part 73 and the valve 74 are also referred to as a “gas adjustment part” 75. A He gas supply source 77 is connected to one gas adjustment part 75, and an Ar gas supply source 78 is connected to the other gas adjustment part 75. A heater 76 heats the He gas supplied from the He gas supply source 77. The heated He gas and the Ar gas supplied from the Ar gas supply source 78 are switched by the control of the valve 74, are supplied to the gas shower head SH2, and are introduced into the processing container 11 from a plurality of gas holes 70 via a buffer chamber 71. The He gas functions as a purge gas that prevents the film formation gas from introducing to the rear surface of the wafer W. In addition, the Ar gas functions as a dilution gas for the film formation gas.

The plurality of gas holes 70 is formed in the lengthwise direction from the upstream side to the downstream side of the gas flow of the film formation gas supplied from the side wall of the processing container 11, and are formed in a slit shape or a hole shape extending in the widthwise direction so as to cover the entire surface of the wafer W when viewed in a plane. As a result, Ar gas, which is a diluting gas, or heated He gas is supplied from each gas hole 70 towards the rear surface of the wafer W supported by the support mechanism 3 in the state in which the flow rate is uniform in the widthwise direction.

He gas is an example of the second gas. The second gas supply source GS2 and the gas shower head SH2 are an example of the second gas supplier configured to supply the second gas to the rear surface of the wafer supported on the support mechanism 3. The second gas is not limited to He gas, and an inert gas may be heated and supplied as the second gas. Further, the dilution gas supplied from the gas shower head SH2 is not limited to Ar gas, and may be an inert gas such as N₂ gas.

When a film is formed the front surface of the wafer W, the support mechanism 3 brings the wafer W close to the second gas supplier (e.g., the position PB in FIG. 1) so as to supply the second gas and the third gas. When a film is formed on the front surface of the wafer W, the second gas supplier supplies an inert gas such as heated He gas as the second gas.

That is, when the film formation gas is supplied and a film forming process is performed on the front surface of the wafer W, the support mechanism 3 lowers the wafer W so as to bring the wafer W close to the second gas supplier, as illustrated in FIG. 2B. As a result, it is possible to prevent a film from being formed on the rear surface of the wafer W by ejecting heated He gas from the second gas supply source GS2 onto the rear surface of the wafer W.

Meanwhile, when a film forming process is performed on the rear surface of the wafer W, the support mechanism 3 raises the wafer W so as to bring the wafer W close to the first gas supplier, as illustrated in FIG. 2A. As a result, it is possible to prevent a film from being formed on the front surface of the wafer W by ejecting heated He gas from the first gas supplier GS1 onto the front surface of the wafer W.

The film forming process in the film forming apparatus 1 having the configuration described above will be briefly described. First, the gate valve 14 is opened, and a wafer W, which is carried in from the outside by a transport arm, is held by the support mechanism 3. After the gate valve 14 is closed and the processing container 11 is sealed, the supply of Ar gas is started from the film formation gas ejection part 4, and exhaust is performed from the exhaust groove 31 so as to adjust the internal pressure of the processing container 11. Next, the support mechanism 3 is raised/lowered to a position at which the film forming process is performed on the front surface of the wafer W.

Thereafter, a film forming process is performed on the front surface of the wafer through the ALD method using DCS, which is a raw material gas, and NH₃, which is a reaction gas as a film formation gas. A method of supplying these film formation gases to the wafer W will be described. The supply of the film formation gas towards the wafer W gripped by the support mechanism 3 is started in the state in which the exhaust is being exhausted from the exhaust groove 31, and the dilution gas is supplied from the gas shower head SH1 towards the front surface of the wafer W. The film formation gas flows from the gas supply pipe 40 into the film formation gas ejection part 4, and the film formation gas diffuses uniformly in the film formation gas ejection part 4. Thereafter, the film formation gas is supplied from the slit 41 of the film formation gas ejection part 4 at a uniform flow rate in the widthwise direction of the wafer W, and flows along the front surface of the wafer W over the entire surface. Thereafter, the film formation gas flows into the exhaust groove 31 while maintaining a parallel flow, and is exhausted from the exhaust pipe 34.

FIG. 4 is a view schematically illustrating a concentration distribution of the film formation gas in the processing container 11. In FIG. 4, the region where the higher concentration of the film formation gas is distributed is indicated by higher density of hatching. As illustrated in FIG. 4, at the position A which is the peripheral edge of the wafer W on the upstream side of the flow of the film formation gas, the film formation gas has a concentration substantially the same as the concentration of the raw material gas and the reaction gas in the gas supplied from the film formation gas ejection part 4. Since the film formation gas is consumed by the film forming process on the wafer W, the concentration of the film formation gas gradually decreases towards the downstream side (that is, the exhaust groove 31 side).

The concentration of the film formation gas is diluted at the most upstream position B where the film formation gas flowing on the front surface of the wafer W and the dilution gas join. The diluted film formation gas is further diluted at the position C where it then joins with the diluted gas, and then flows downstream while being diluted at positions D, E, and F, in this order.

Therefore, the concentration (concentration of the raw material gas or the reaction gas) of the film formation gas becomes lower as it is located on the downstream side, for example, as illustrated in FIG. 4. At this time, the film formation gas is supplied at a uniform flow rate in the widthwise direction, and the dilution gas is supplied from the slit-shaped gas holes 50 extending in the widthwise direction of the flow of the film formation gas at a uniform flow rate in the widthwise direction of the flow of the film formation gas. Then, as illustrated in the schematic view in FIG. 4, the concentration of the film formation gas is uniform in the widthwise direction of the flow of the film formation gas.

Then, the rotation mechanism 82 is driven so as to rotate the wafer W around the axis of the support 81, which supports the stage 3a in FIGS. 2A and 2B. When the wafer W is rotated in the atmosphere in which the concentration of the film formation gas becomes uniform in the widthwise direction of the flow of the film formation gas and continuously changes in one direction as illustrated in FIG. 4, a portion of the wafer W other than the rotation center of the support 81 repeatedly moves between the region where the concentration of the film formation gas is high and the region where the concentration of the film formation gas is low. That is, when viewed from each portion of the wafer W, the state in which the concentration of the film formation gas in the atmosphere gradually decreases and the state in which the concentration of the film formation gas gradually increases are repeated. When the wafer W makes one rotation, the film thickness is uniform in the circumferential direction because the portions at the same distance from the center pass through the same region, and the film thickness is determined according to a concentration change pattern with respect to a time transition when the portions make one rotation. Therefore, the thin film formed on the front surface of the wafer W has a concentric film thickness distribution, and the film thickness distribution is determined by the concentration distribution in the flow direction of the film formation gas near the front surface of the wafer W. As described above, the concentration distribution of the film formation gas is determined by the degree of dilution with the diluting gas supplied from the gas hole 50. Therefore, by changing the flow rate of the dilution gas supplied from the gas holes 50 by the gas adjustment part 55, it is possible to adjust the concentration distribution of the film formation gas. When this process is executed by changing the position of the wafer W by the support mechanism 3, it is possible to form a film on the front surface and the rear surface.

Referring back to FIG. 1, the film forming apparatus 1 has a controller 100 configured to control the operation of the entire apparatus. The controller 100 performs a film forming process according to a recipe stored in a memory such as a read only memory (ROM) or random access memory (RAM). In the recipe, apparatus control information for process conditions, such as a process time, pressure (gas evacuation), radio-frequency power and voltage, various gas flow rates, the temperature in the processing container (e.g., the temperature of the upper electrode, the temperature of the side wall of the processing container, the temperature of the wafer W, or the temperature of the electrostatic chuck), and the temperature of coolant output from the chiller, are set. According to the procedure of the recipe, the controller 100 controls the supply of first to third gases and controls the film formation on the front surface of the wafer W and the film formation on the rear surface of the wafer W.

In addition, a recipe representing these programs and processing conditions may be stored in a hard disc or semiconductor memory. In addition, the recipe may be set at a predetermined position to be read out in the state of being stored in a storage medium readable by a portable computer, such as a CD-ROM or a DVD.

[Switching Between Film Formation on Front Surface and Film Formation on Rear Surface of Wafer]

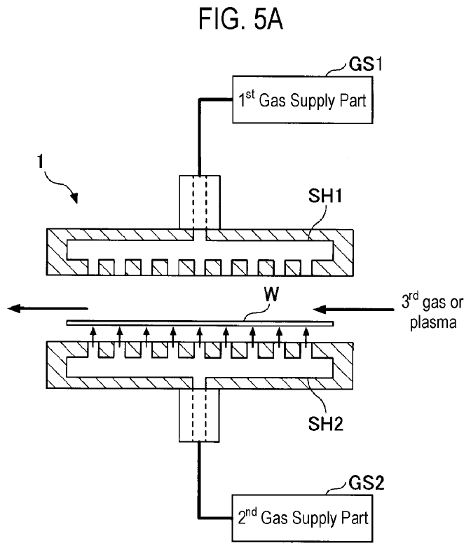

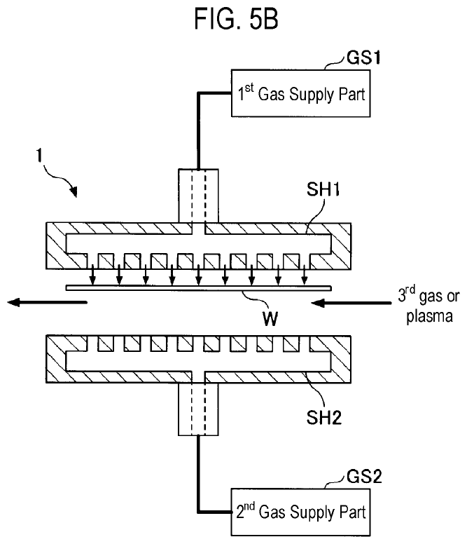

Switching between the film formation on the front surface and the film formation on the rear surface of a wafer W will be described with reference to FIGS. 5A and 5B, which illustrate the film forming apparatus 1 of FIG. 1 in a simplified manner. In this example, the film forming apparatus 1 performs film formation through ALD, but is not limited thereto. For example, the film forming apparatus 1 may perform film formation through plasma-enhanced chemical vapor deposition (PECVD).

When forming a film on the front surface of the wafer W, the film formation is performed in the state in which the wafer W is brought close to the second gas supplier GS2, as illustrated in FIG. 5A. At this time, the gas and plasma is sufficiently suppressed from being introduced to the surface (here, the rear surface) of the wafer W opposite the film formation surface by supplying heated He purge gas to the rear surface of the wafer W in the form of a shower through the gas shower head SH2 from the second gas supplier GS2.

When a film is formed on the rear surface of the wafer W, the film formation is performed in the state in which the wafer W is brought close to the first gas supplier GS1, as illustrated in FIG. 5B. At this time, the gas and plasma is sufficiently suppressed from being introduced to the surface (here, the front surface) of the wafer W opposite the film formation surface by supplying heated He purge gas to the front surface of the wafer W in the form of a shower through the gas shower head SH1 from the first gas supplier GS1.

[When Forming Film on Front Surface of Wafer W]

Specifically, when forming a film on the front surface of the wafer W, as illustrated in FIG. 5A, the controller 100 lowers the support mechanism 3 so as to bring the support mechanism 3 close to the second gas supplier GS2 and to bring the wafer W close to the gas shower head SH2, and then supplies the second gas and the third gas so as to form a film on the front surface of the wafer W. The second gas is heated He gas, and the third gas is a raw material gas for film formation.

In this case, the controller 100 opens the valve 74 connected to the He gas supply source 77 of the second gas supply source GS2 illustrated in FIG. 1 and closes the valve 74 connected to the Ar gas supply source 78. In addition, the controller 100 opens the valve 44 of the third gas supply source GS3 and closes the valves 48 and 62.

In the plasma process, plasma is generated not only in the space between the wafer W and the shower head SH1, but also in the space between the wafer W and the shower head SH2, which causes film formation on the rear surface of the wafer W. In contrast, in the present embodiment, while a film is formed on the front surface of the wafer W, heated He gas is introduced from the shower head SH2 and is sprayed onto the rear surface of the wafer W. As a result, the film formation gas is suppressed from being introduced to the rear surface of the wafer W, and the film formation on the rear surface of the wafer W is prevented.

In addition, the introduction of the He gas reduces the electron density of plasma in this space, which has the effect of suppressing the ignition of plasma. As a result, plasma generation in the space between the wafer W and the shower head SH2 can be suppressed by a mechanism for purging the heated He gas from the shower head SH2, and film formation on the rear surface of the wafer W can be prevented.

In the film forming process, a predetermined film formation is performed on the front surface of the wafer W using the supplied raw material gas for film formation. In this case, the controller 100 closes the valve 54 connected to the He gas supply source 57 of the first gas supply source GS1 illustrated in FIG. 1 and opens the valve 54 connected to the Ar gas supply source 58. As a result, Ar gas is supplied from the shower head SH1, and the raw material gas for film formation is diluted to a predetermined concentration.

Next, the controller 100 closes the valve 44 to stop the supply of the raw material gas and emits the plasma of NH₃ gas from the remote plasma generator 65 so as to fix the raw material gas on the front surface of the wafer W. Here, the controller 100 controls the switching between the raw material gas and the plasma, but the present disclosure is not limited thereto, and may control the switching between the raw material gas, the reaction gas and the plasma. In addition, while switching between the raw material gas and the plasma, Ar gas may be supplied from the Ar gas supply source 61 to purge the interior of the processing container 11.

[When Forming Film on Rear Surface of Wafer W]

In addition, when forming a film on the rear surface of the wafer W, as illustrated in FIG. 5B, the controller 100 raises the support mechanism 3 so as to bring the support mechanism 3 close to the first gas supplier GS1 and to bring the wafer W close to the gas shower head SH1, and then supplies the first gas and the third gas so as to form a film on the rear surface of the wafer W. The first gas is heated He gas, and the third gas is a raw material gas for film formation.

In this case, the controller 100 opens the valve 54 connected to the He gas supply source 57 of the first gas supply source GS1 illustrated in FIG. 1 and closes the valve 54 connected to the Ar gas supply source 58. In addition, the controller 100 opens the valve 44 of the third gas supply source GS3 and closes the valves 48 and 62. As a result, in the present embodiment, while a film is being formed on the rear surface of the wafer W, heated He gas is introduced from the shower head SH1 and is sprayed onto the front surface of the wafer W. As a result, the film formation gas is suppressed from being introduced to the front surface of the wafer W, and the film formation on the front surface of the wafer W is prevented.

In addition, by introducing He gas into the space between the wafer W and the shower head SH1, the ignition of plasma can be suppressed, plasma generation in the space between the wafer W and the shower head SH1 can be suppressed, and thus film formation on the rear surface of the wafer W can be prevented.

In this case, when a predetermined film formation is performed on the rear surface of the wafer W using the supplied raw material gas for film formation, the controller 100 closes the valve 74 connected to the He gas supply source 77 of the second gas supply source GS2 illustrated in FIG. 1 and opens the valve 74 connected to the Ar gas supply source 78. As a result, Ar gas is supplied from the shower head SH2, and the raw material gas for film formation is diluted to a predetermined concentration.

The controller 100 may close the valve 44 to stop the supply of the raw material gas and may emit plasma from the remote plasma generator 65 so as to fix the raw material gas on the front surface of the wafer W. Further, the controller 100 may control switching between the raw material gas, the reaction gas and the plasma. Ar gas may be supplied from the Ar gas supply source 61 at a predetermined timing to purge the interior of the processing container 11.

As described above, in the film forming apparatus 1 according to the present embodiment, heated He gas is supplied from the shower heads SH1 and SH2 to heat the wafer W while purging the surface of the wafer W on the side where film formation is not performed. As a result, it is possible to prevent a film from being formed on the surface of the wafer W on which it is not intended to perform film formation, and it is possible to raise the temperature of the wafer W at a high speed with this configuration in which the wafer W is not in contact with the heater. In this case, although the film formation temperature is about 100 degrees C. to 500 degrees C., it is necessary to raise the temperature of the gas 800 degrees C. before the gas is released into the vacuum space in consideration of the large heat loss due to expansion when the heated He gas is released into the vacuum space. Regarding this, it is possible to raise the temperature of the gas to 800 degrees C. using a high temperature gas heater.

When film formation is performed on the front surface of the wafer W, the distance between the wafer W and the shower head SH2 is set to be as narrow as possible. When film formation is performed on the rear surface of the wafer W, the distance between the wafer W and the shower head SH1 is set to be as narrow as possible. As a result, the He gas leaks only from the outer peripheries of the shower heads SH1 and SH2, and it is possible to make it difficult for the film forming gas to enter the surface of the wafer W on the side where film formation is not performed.

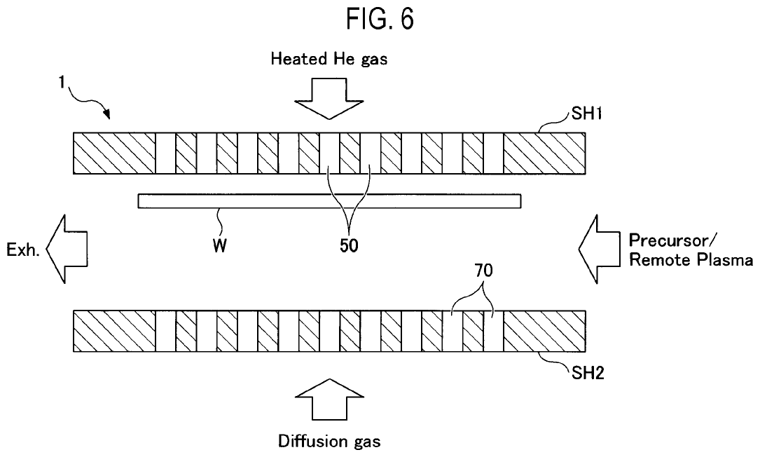

When forming a film on the rear surface of the wafer W, as illustrated in FIG. 6, the third gas supplier GS3 switches between the supply of the side flow precursor (the raw material gas for film formation) and the supply of plasma supplied from the remote plasma generator 65 so as to supply the precursor from the side wall of the processing container 11. In addition, heated He gas is supplied from the shower head SH1 to heat the wafer W. In addition, a dilution gas such as Ar gas is introduced from the shower head SH2 so as to adjust a film formation concentration.

When forming a film on the front surface of the wafer W, the third gas supplier GS3 switches between the supply of the side flow precursor (the raw gas of film formation) and the supply of the plasma supplied from the remote plasma generator 65, so as to supply the plasma after supplying the precursor in the radial direction of the wafer W supported on the support mechanism 3. In addition, heated He gas is supplied from the shower head SH2 to heat the wafer W. In addition, a dilution gas such as Ar gas is introduced from the shower head SH1 so as to adjust a film formation concentration.

In this configuration, since it becomes possible to supply the side flow raw material gas and plasma from the side wall of the film forming apparatus 1, it becomes possible to switch between the film formation on the front surface and the film formation on the rear surface of the wafer W. This makes it possible to compensate for the warpage of the wafer W caused due to the stress of the film.

### MODIFICATION

In the film forming apparatus 1 according to an embodiment, the first gas supply source GS1 and the second gas supply source GS2 are installed, but they may be integrated. For example, when the second gas supply source GS2 is eliminated, the first gas supply source GS1 is connected to both the gas shower heads SH1 and SH2. Then, when forming a film on the front surface of the wafer, the valves 54 are controlled so as to supply a dilution gas to the gas shower head SH1 and to supply heated He gas to the gas shower head SH2. When forming a film on the rear surface of the wafer, the valves 54 are controlled so as to supply dilution gas to the gas shower head SH2 and to supply heated He gas to the gas shower head SH1. Of course, as a premise, the position of the wafer W is controlled by the support mechanism 3 so as to approach the first gas supplier GS1 or the second gas supplier GS2 depending to the surface on which a film is formed. As a result, the first gas supply source GS1 or the second gas supply source GS2 may be integrated so as to simplify the configuration of the film forming apparatus 1.

Instead of the support mechanism 3 or in addition to the support mechanism 3, a grip part configured to grip and hold the edge of the wafer W may be provided, and the grip part may be rotatable using a rotary transport arm for the grip part. Since the front surface and the rear surface of the wafer W can be inverted by rotation, it is possible to form a film on the front side and the rear surface of the wafer. This makes it possible to use the processing container 11 without significant change of the existing processing container 11.

The wafer W may be reversed outside the processing container 11. For example, an aligner for positioning a wafer W may be provided with a rotation mechanism for reversing the wafer W. After reversing the wafer W, the wafer W may be returned to the interior of the processing container 11 so as to form a film on the rear surface of the wafer W. In this case, by providing the rotation mechanism outside the processing container 11, it is not necessary to change the configuration inside the processing container 11, so that the film forming apparatus 1 can be easily introduced.

The raw material gas and the reaction gas may be supplied from the shower head SH1. In this case, the DCS supply source 43 configured to supply DCS, which is an example of the raw material gas, and respective parts (the valve 44 and the flow rate adjustment part 45) may be connected to the gas supply pipe 52. Similarly, the NH₃ supply source 47 configured to supply NH₃, which is an example of the reaction gas, and respective parts (the valve 48 and flow rate adjusting part 49) may be connected to the gas supply pipe 52. In this case, the DCS supply source 43, the valve 44, the flow rate adjustment part 45, the NH₃ supply source 47, the valve 48, and the flow rate adjustment part 49 are an example of the third gas supplier configured to supply the third gas to at least one of the front surface and the rear surface of the wafer W supported on the support mechanism 3.

When forming a film on the front surface of the wafer W while supplying a raw material gas and a reaction gas from the shower head SH1, the wafer W is brought close to the shower head SH2 (e.g., the position PB in FIG. 1) by the support mechanism 3. Then, the raw material gas and the reaction gas as the third gases, which are the film formation gases, are alternately supplied from the gas shower head SH1 towards the front surface of the wafer W. In addition, Ar gas as the first gas, which is a dilution gas, is supplied from the gas shower head SH1 towards the front surface of the wafer W. The film formation gas is introduced into the processing container 11 from the plurality of gas holes 50 via the buffer chamber 51 of the gas shower head SH1. During this period, an inert gas such as heated He gas is supplied from the gas shower head SH2 as the second gas. As a result, it is possible to prevent a film from being formed on the rear surface of the wafer W by ejecting the heated He gas onto the rear surface of the wafer W.

When forming a film on the rear surface of the wafer W, the support mechanism 3 raises the wafer W so as to bring the wafer W close to the first gas supplier (e.g., the position PA in FIG. 1). Then, the film forming gas is supplied from the third gas supplier to the rear surface of the wafer W supported on the support mechanism 3. In addition, Ar gas is supplied from the gas shower head SH2 towards the rear surface of the wafer W. During this period, the inert gas such as heated He gas is supplied from the gas shower head SH1. As a result, it is possible to prevent a film from being formed on the front surface of the wafer W by ejecting the heated He gas onto the front surface of the wafer W. Regarding the switching between the supply of the third gas from the third gas supplier and the supply of plasma from the remote plasma generator, the valves 44 may be used for switching even when the third gas is supplied from the gas shower head SH1.

As described above, with the film forming apparatus 1 of the present embodiment, it is possible to form a film on the front surface and the back surface of the wafer, and it is possible to compensate for the warpage of a wafer caused due to a film.

It should be considered that the film forming apparatus and the film forming method according to the embodiments disclosed herein are illustrative and not restrictive in all aspects. The above embodiments may be modified and improved in various forms without departing from the scope and spirit of the appended claims. The matters described in the above embodiment may take other configurations without contradiction, and may be combined without contradiction.

The processing apparatus of the present disclosure is applicable to any of a capacitively coupled plasma (CCP) type, an inductively coupled plasma (ICP) type, a radial line slot antenna (RLSA) type, an electron cyclotron resonance plasma (ECR) type, and a helicon wave plasma (HWP) type.

In this specification, a wafer W has been described as an example of a substrate. However, the substrate is not limited thereto, and may be any of various substrates used for a flat panel display (FPD), a printed circuit board, or the like.

The present international application claims priority based on Japanese Patent Application No. 2018-150525 filed on Aug. 9, 2018, the disclosure of which are incorporated herein in its entirety by reference.

### EXPLANATION OF REFERENCE NUMERALS

1: film forming apparatus, 2: lifter pin, 3: support mechanism, 3a: stage, 11: processing container, 50: gas hole, 51: buffer chamber, 65: remote plasma generator, 70: gas hole, 71: buffer chamber, 80: jig, 81: support, 82: rotation mechanism, 83: lifting mechanism, 85, 86: magnetic seal, 100: controller, GS1: first gas supply source, GS2: second gas supply source, GS3: third gas supply source, SH1: gas shower head, SH2: gas shower head

1. A film forming apparatus comprising:
a processing container;
a support mechanism configured to support a substrate to be capable of being raised and lowered;
a first gas supplier configured to supply a first gas to a front surface of the substrate supported on the support mechanism;
a second gas supplier configured to supply a second gas to a rear surface of the substrate supported on the support mechanism; and
a third gas supplier configured to supply a third gas to at least one of the front surface and the rear surface of the substrate supported on the support mechanism.

2. The film forming apparatus of claim 1, wherein the third gas supplier is configured to supply the third gas in a radial direction of the substrate supported on the support mechanism.

3. The film forming apparatus of claim 1, wherein the first gas supplier is configured to supply a heated inert gas as the first gas when forming a film on the rear surface, and
the second gas supplier is configured to supply a heated inert gas as the second gas when forming the film on the front surface.

4. The film forming apparatus of claim 1, further comprising:
a controller configured to control a film formation on the front surface of the substrate and the rear surface of the substrate by controlling the supply of the first gas, the second gas, and the third gas.

5. The film forming apparatus of claim 4, further comprising:
a remote plasma generator configured to supply a plasma in the radial direction of the substrate supported on the support mechanism, and
wherein the controller is configured to switch between the supply of the third gas from the third gas supplier and the supply of the plasma from the remote plasma generator.

6. The film forming apparatus of claim 4, wherein the controller is configured to bring the substrate close to the second gas supplier by the support mechanism, and to supply the second gas and the third gas so as to form the film on the front surface of the substrate.

7. The film forming apparatus of claim 6, wherein the controller is configured to supply the first gas so as to dilute the third gas.

8. The film forming apparatus of claim 4, wherein the controller is configured to bring the substrate close to the first gas supplier by the support mechanism, and to supply the first gas and the third gas so as to form the film on the rear surface of the substrate.

9. The film forming apparatus of claim 8, wherein the controller is configured to supply the second gas so as to dilute the third gas.

10. A method of forming a film using a film forming apparatus including a support mechanism configured to support a substrate to be capable of being raised and lowered; a first gas supplier configured to supply a first gas to a front surface of the substrate supported on the support mechanism; a second gas supplier configured to supply a second gas to a rear surface of the substrate supported on the support mechanism; and a third gas supplier configured to supply a third gas to at least one of the front surface and the rear surface of the substrate supported on the support mechanism, the method comprising:
controlling film formation on the front surface of the substrate and the rear surface of the substrate by controlling supply of the first gas, the second gas, and the third gas.

11. The method of claim 10, wherein the controlling the film formation includes:
controlling the film formation on the front surface of the substrate by approaching the substrate to the second gas supplier by raising and lowering the support mechanism, and supplying the second gas and the third gas; and
controlling the film formation on the rear surface of the substrate by approaching the substrate to the first gas supplier by raising and lowering the support mechanism, and supplying the first gas and the third gas.
